(19) United States
(12) Patent Application Publication
(10) Pub. No.: US 2010/0327173 A1
(43) Pub. Date: Dec. 30, 2010

(54) Integrated Direct Conversion Detector Module

(76) Inventors: Charles Gerard Woychik, Niskayuna, NY (US); James Rose, Guilderland, NY (US); John Eric Tkaczyk, Delanson, NY (US); Jonathan Short, Saratoga Springs, NY (US); Yanfeng Du, Rexford, NY (US)

Correspondence Address: GENERAL ELECTRIC COMPANY;GLOBAL RESEARCH, ONE RESEARCH CIRCLE, BLDG. K1-3A59, NISKAYUNA, NY, 12309, US

(21) Appl. No.: 12/494,257

(22) Filed: Jun. 29, 2009

(51) Int. Cl. G01T 1/24; H01L 21/50

(52) U.S. Cl. 250/370.09; 438/66; 257/E21.499

(57) ABSTRACT

A detector module comprises: a direct conversion crystal for converting incident photons into electrical signals, the direct conversion crystal having an anode layer deposited on a first surface and a cathode layer deposited on a second surface; a redistribution layer deposited on the anode layer, the redistribution layer configured to adapt a pad array layout of the direct conversion crystal to a predetermined lead pattern; an integrated circuit in electrical communication with the direct conversion crystal; and a plurality of input/output electrical paths connected to the redistribution layer to provide connectivity between the imaging module and another level of interconnect.

### BACKGROUND OF THE INVENTION

The subject matter disclosed herein relates to electronic imaging systems and, more particularly, to modular imaging sensor arrays.

X-ray and computed tomography imaging systems have been utilized for observing interior aspects of a patient or objects of interest. A detecting device is typically positioned to detect radiation attenuated from passing through the patient or object. There is shown in the isometric diagrammatical illustration of FIG. 1 a “third generation” CT imaging system 10 configured to perform computed tomography imaging on a patient 22 by means of photon counting and energy discrimination of x-rays at high flux rates, as is known in the relevant art. The CT imaging system 10 comprises a gantry 12, with a collimator assembly 18, a data acquisition system 32, and an x-ray source 14 disposed on the gantry 12 as shown.

Operation of the CT imaging system 10 may be described with reference to the functional block diagram of FIG. 2. The x-ray source 14 projects a beam of x-rays 16 through the patient 22 onto a plurality of detector modules 20 in a detector assembly 11. The detector assembly 11 includes the collimator assembly 18, the detector modules 20, and the data acquisition system 32. In a typical embodiment, the detector assembly 11 may comprise sixty-four rows of pixel elements to enable sixty-four simultaneous “slices” of data to be collected with each rotation of the gantry 12.

The plurality of detector modules 20 sense the x-rays remaining after partial attenuation upon passing through the patient 22, and the data acquisition system 32 converts the data to digital signals for subsequent processing. Each detector module 20 in a conventional system produces an analog electrical signal that represents the intensity of an attenuated x-ray beam after it has passed through the patient 22. During a scan to acquire x-ray projection data, the gantry 12 rotates about a center of rotation 24 along with the x-ray source 14 and the detector assembly 11.

The rotation of the gantry 12 and the operation of the x-ray source 14 are controlled by a control mechanism 26. The control mechanism 26 includes an x-ray generator 28 that provides power and timing signals to the x-ray source 14, and a gantry motor controller 30 that controls the rotational speed and position of the gantry 12. An image reconstruction processor 34 receives sampled and digitized x-ray data from the data acquisition system 32 and performs high-speed reconstruction. The reconstructed image is applied as an input to a computer 36 which can also store the image in a mass storage device 38. Commands and scanning parameters are used by the computer 36 to provide control input signals and information to the data acquisition system 32, the x-ray generator 28, and the gantry motor controller 30.

In the present state of the art, healthcare and security-based imaging applications are migrating to direct conversion detector systems. The integration of a readout integrated circuit with a detector crystal in an imaging device 40, shown in FIG. 3, may serve to improve performance of an imaging module. However, present imaging module designs typically use a ceramic substrate 44 to support a detector crystal 42. The coefficient of thermal expansion (CTE) of the ceramic substrate 44 may be on the order of 6.0 ppm/° C., and thus closely matches thermal properties of a direct conversion material, such as CZT (CdZnTe), which may have a CTE on the order of 5.9 ppm/° C. The associated integrated circuit 46 may be mounted to the backside of the ceramic substrate 44 using a suitable attachment method, here denoted as an attachment means 48. The attachment means may comprise, for example, a flip chip attachment or a wire bond attachment. Alternatively, the integrated circuit 46 can be mounted in a conventional package and attached to the backside of the ceramic substrate 44. In the alternative configuration, the backside of the integrated circuit 46 is exposed, and allows for attachment of a heat sink to provide cooling for the integrated circuit 46.

However, such conventional configurations introduces noise and added interconnect complexity because of the location of the ceramic substrate 44 between the integrated circuit 46 and the detector crystal 42. Moreover, as the ceramic substrate 44 is larger than the detector crystal 42, the detector crystals 42 cannot be arrayed in an efficient manner.

What is needed is an improved device and method of imaging that provides an imaging sensor array producing less noise and requiring fewer interconnections than prior art devices.

### BRIEF DESCRIPTION OF THE INVENTION

In one aspect of the present invention, a detector module comprises: a direct conversion crystal for converting incident photons into electrical signals, the direct conversion crystal having an anode layer deposited on a first surface and a cathode layer deposited on a second surface; a redistribution layer deposited on the anode layer, the redistribution layer configured to adapt a pad array layout of the direct conversion crystal to a predetermined lead pattern; an integrated circuit in electrical communication with the direct conversion crystal; and a plurality of input/output electrical paths connected to the redistribution layer to provide connectivity between the imaging module and another level of interconnect.

In another aspect of the present invention, an imaging sensor array comprises: a support structure; a plurality of imaging modules attached to the support structure, at least one of the imaging modules including a redistribution layer attached to an anode layer on a direct conversion crystal; an outer layer overlying and attached to the plurality of imaging modules by a thermal plastic conductive adhesive; and a plurality of input/output electrical paths connected to the imaging modules to provide connectivity between the imaging sensor array and a second level support structure.

In still another aspect of the present invention, a method of fabricating an imaging sensor array comprises: providing a plurality of imaging modules, each imaging module fabricated from a direct conversion crystal having a redistribution layer for attaching a readout integrated circuit to an anode layer on the direct conversion crystal, each readout integrated circuit being smaller in size than the direct conversion crystal; attaching the plurality of imaging modules to a support structure in a predetermined pattern; and providing a plurality of input/output electrical paths between the imaging modules and another level of interconnect.

Other devices and/or methods according to the disclosed embodiments will become or are apparent to one with skill in the art upon review of the following drawings and detailed description. It is intended that all such additional devices and methods are within the scope of the present invention, and are protected by the accompanying claims.

### BRIEF DESCRIPTION OF THE DRAWINGS

FIG. 1 is an isometric diagrammatical view of a computed tomography imaging system, in accordance with the present art;

FIG. 2 is a functional block diagram of the computed tomography imaging system of FIG. 1;

FIG. 3 is a diagrammatical cross sectional view of a direct conversion crystal mounted on a ceramic substrate, in accordance with the present art;

FIG. 4 is an exemplary embodiment of an imaging module comprising an integrated circuit mounted to a direct conversion crystal via a redistribution layer, in accordance with an aspect of the present invention;

FIG. 5 is a diagrammatical edge view of an imaging sensor array comprising a plurality of the imaging modules of FIG. 4;

FIG. 6 is an alternative exemplary embodiment of the imaging module of FIG. 4 showing wire bonds attaching the integrated circuit to the redistribution layer;

FIG. 7 is an alternative exemplary embodiment of the imaging module of FIG. 4 showing a ball or column grid array module attaching the integrated circuit to the redistribution layer with a pigtail attached to the redistribution layer;

FIG. 8 is an alternative exemplary embodiment of the imaging module of FIG. 7 showing the pigtail attached to the ball or column grid array;

FIG. 9 is a diagrammatical view showing a testable subassembly of the imaging module of FIG. 8;

FIG. 10 is a diagrammatical isometric view of an x-y array of a plurality of the imaging modules of FIG. 4;

FIG. 11 shows an alternative exemplary embodiment of the imaging sensor array of FIG. 4, showing rectangular imaging modules arranged in a staggered array;

FIG. 12 shows an alternative exemplary embodiment of the imaging sensor array of FIG. 4, showing hexagonally-shaped imaging modules arranged in a close packing array;

FIG. 13 shows an alternative exemplary embodiment of the imaging module of FIG. 4 showing solder balls for attachment to a substrate;

FIG. 14 is diagrammatical edge view of an imaging sensor array comprising a plurality of the imaging modules of FIG. 11;

FIG. 15 an alternative embodiment of the imaging sensor array of FIG. 12 including thermal vias and heatsinks;

FIG. 16 is a diagrammatical illustration showing metal-coated plastic balls used in the imaging sensor array of FIG. 10; and

FIG. 17 is a diagrammatical illustration showing copper balls used in the imaging sensor array of FIG. 10.

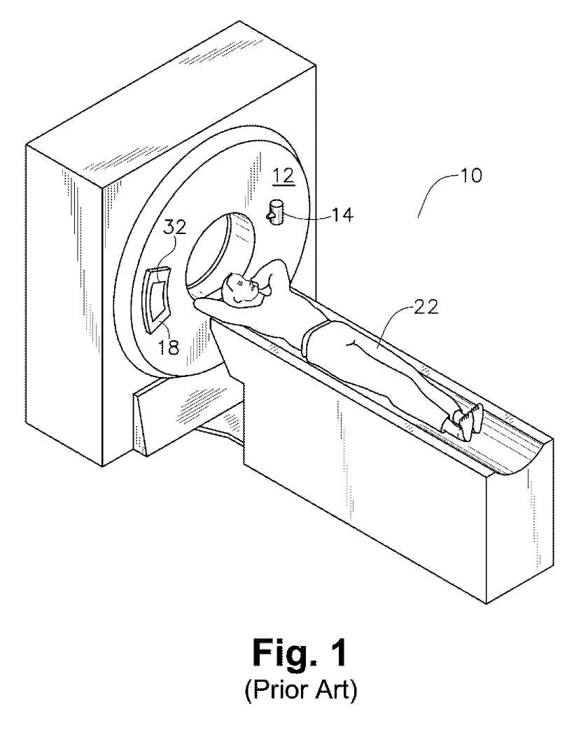

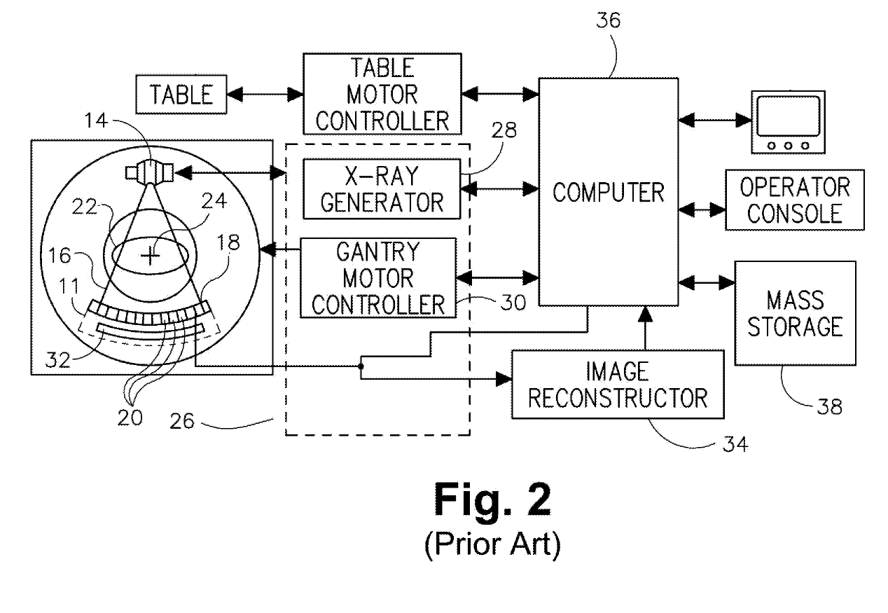

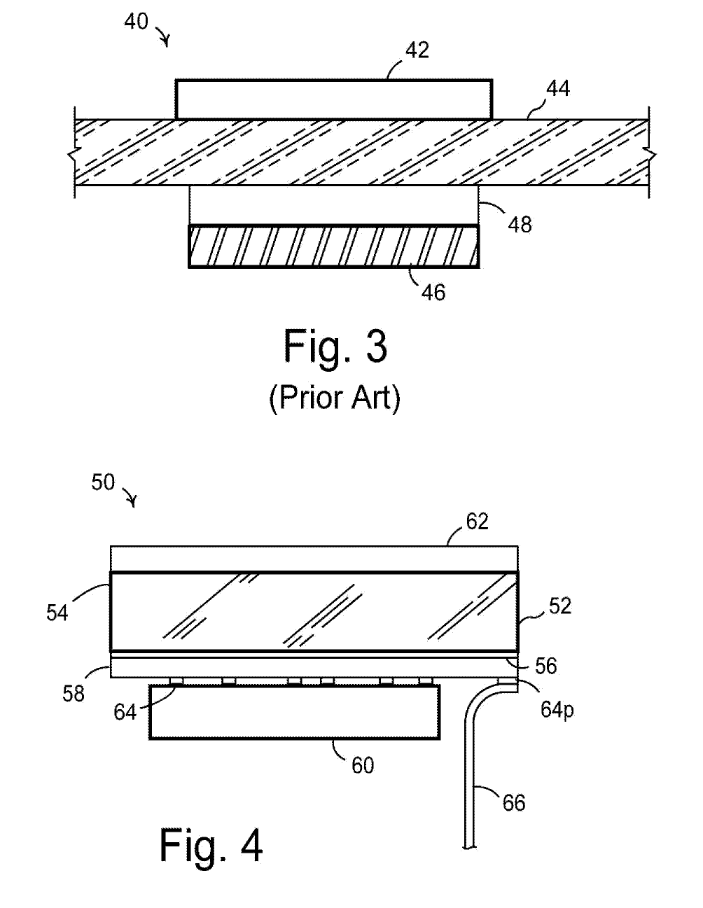

### DETAILED DESCRIPTION OF THE INVENTION

The present invention provides for an imaging module having an interposer, or redistribution layer, created on the pixel side of a direct conversion crystal. This design serves to adapt a crystal pad array layout to that of a lead configuration on a readout integrated circuit. The redistribution layer provides for an optimized imaging module design with minimum interconnect complexity and low capacitance, reducing noise propagation by directly attaching the readout integrated circuit to the backside of the direct conversion crystal. The resulting imaging module component can be used as an individual sensor array, or may be tiled with other imaging modules to create a sensor array having a much greater imaging surface than an individual imaging module.

Referring now to FIG. 4, a diagrammatical edge view illustrating a stack up of an imaging module 50, in accordance with one aspect of the present invention. The imaging module 50 comprises a direct conversion crystal 52 for receiving incident radiation, such as from an x-ray source (not shown), and converting to electrical signals or current, as well known in the relevant art. A cathode layer 62 may comprise a metal film deposited on a crystal face 54 (i.e., the input side) of the direct conversion crystal 52. A redistribution layer 58 may be disposed on an anode layer 56 (i.e., the pixel side of the crystal 52) to provide an electrical interface between a readout integrated circuit 60 and the direct conversion crystal 52. During fabrication of the imaging module 50, the redistribution layer 58 may be applied to the direct conversion crystal 52 at the wafer level.

The direct conversion crystal 52 may comprise a semiconductor material such as, for example, cadmium telluride (CdTe) or cadmium zinc telluride (CdZnTe), but one skilled in the art will recognize that other materials capable of direct conversion of electromagnetic energy into electrical signals representative of energy discriminating information or photon count data may be used for a direct conversion crystal. During operation of the imaging module 50, the cathode layer 62 and the anode layer 56 may be biased to create an electric field across the direct conversion crystal 52. X-ray photons received at the imaging module 50 create electrical signals inside the direct conversion crystal 52 and are accordingly detected or collected to provide information to a data acquisition system (not shown).

The redistribution layer 58 may be configured, by methods known in the art, to adapt the pad array layout (not shown) of the direct conversion crystal 52 to the lead pattern (not shown) of the integrated circuit 60. The redistribution layer 58 thus serves to provide a plurality of electrical interconnection paths from the direct conversion crystal 52 to a plurality of redistribution pads 64 on an outer surface of the redistribution layer 58. In an exemplary method of fabrication, leads from the integrated circuit 60 may be electrically attached to the plurality of redistribution pads 64 during fabrication of the imaging module 50. Preferably, the integrated circuit 60 may be configured as a “flip chip” to provide for soldering of the leads of the integrated circuit 60 to the redistribution pads 64.

One or more flex attachments, such as a flex “pigtail” 66, may be soldered to one or more corresponding redistribution perimeter pads 64p on the redistribution layer 58 to provide a plurality of input/output electrical paths for the integrated circuit 60. The input/output paths may thus provide connectivity between the imaging module 50 and a remote electrical imaging circuit or a data acquisition system (not shown), for example. The input/output paths may also carry input and output signals to another level of interconnect.

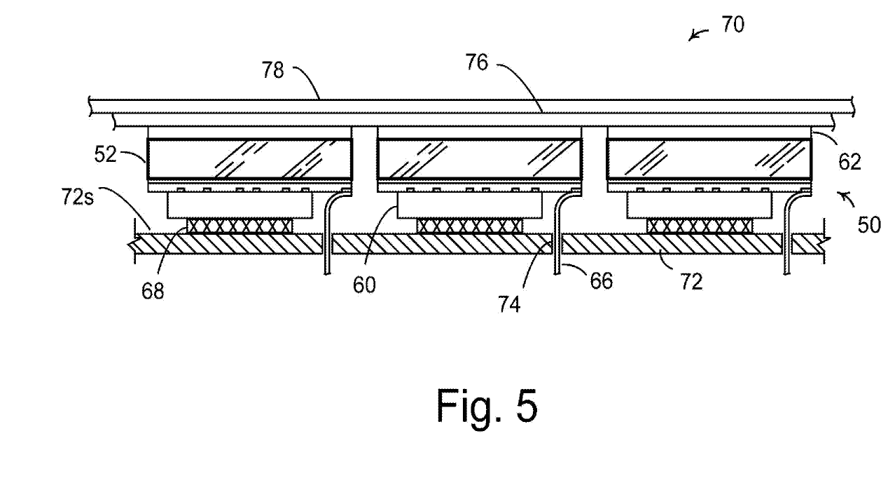

A plurality of imaging modules 50 may be arranged in a predetermined one-dimensional or two-dimensional pattern on a support structure 72 or supporting substrate, such as a copper rail, to form an imaging sensor array 70, shown in diagrammatical end view in FIG. 5. A thermal interface pad 68 may be positioned between one or more integrated circuits 60 and the support structure 72. A plurality of conductor pass-thru openings 74 may be provided in the support structure 72 so as to allow each flex pigtail 66 in a corresponding imaging module 50 to pass through the support structure 72. It can be appreciated by one skilled in the relevant art that the support structure 72 may have a substantially planar mounting surface 72s, as shown, or may have a substantially convex or concave surface (not shown) as may be adapted to a particular imaging application. An outer layer 78 may be attached to the cathode layers 62 by a thermal plastic conductive adhesive 76 so as to overly the plurality of imaging modules 50. In an exemplary embodiment, the outer layer 78 may comprise a carbon fiber gold flash film.

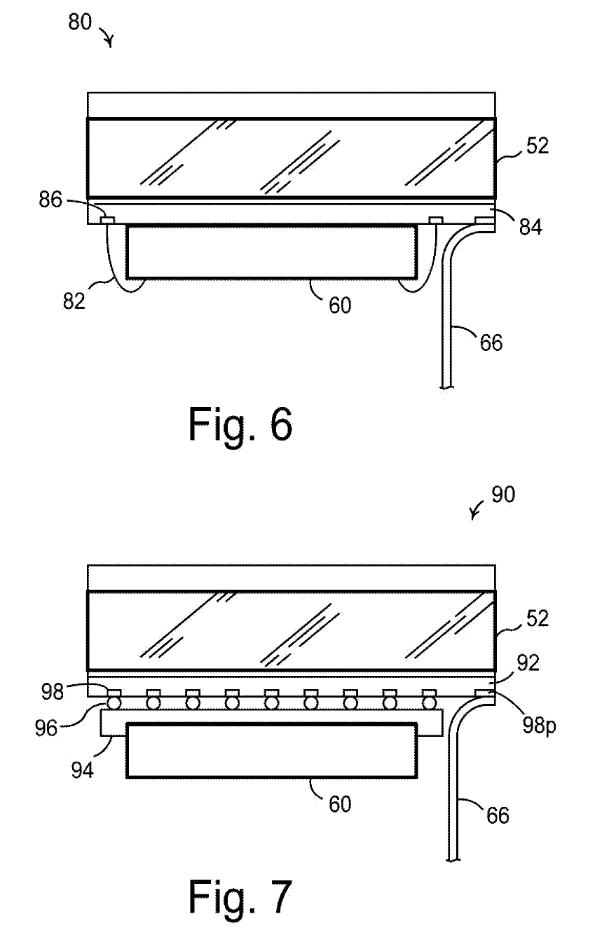

In still another exemplary embodiment, shown in FIG. 6, the integrated circuit 60 may be attached by a plurality of wire bonds 82 to a plurality of redistribution pads 86 in a redistribution layer 84 to form an imaging module 80, in accordance with an aspect of the present invention. The imaging module 80 comprises the direct conversion crystal 52 and the flex pigtail 66 attached to the redistribution layer 84, and may thus be used in the imaging sensor array 70, shown in FIG. 5, in place of one or more of the imaging modules 50.

An integrated circuit can be emplaced in a plastic ball or column grid array module or package, for example, as standardized by the Joint Electron Device Engineering Council (JEDEC). FIG. 7 shows yet another exemplary embodiment of an imaging module 90 having the integrated circuit 60 attached to a redistribution layer 92 by a JEDEC ball or column grid array module 94. The JEDEC ball or column grid array module 94 may be soldered to the redistribution pads 98 in the redistribution layer 92 by a plurality of solder interconnects 96. The flex pigtail 66 may be attached to one or more redistribution perimeter pads 98p.

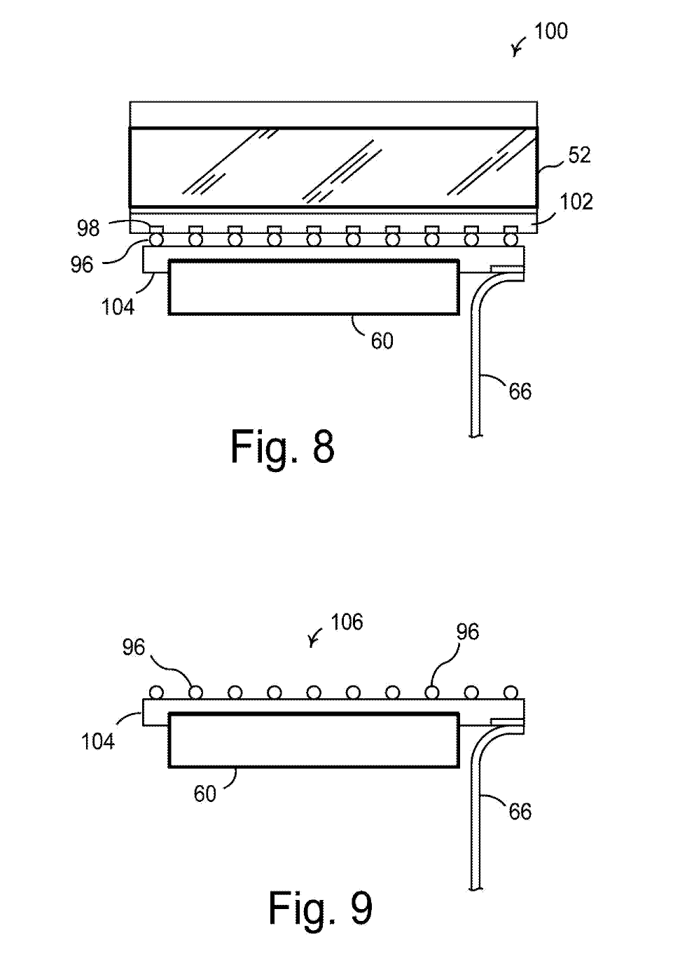

In another exemplary embodiment, shown in FIG. 8, an imaging module 100 comprises the direct conversion crystal 52 with a redistribution layer 102 attached to the anode side. The integrated circuit 60 may be emplaced in a plastic ball or column grid array module 104, with the flex pigtail 66 attached to the ball or column grid array module 104. The ball or column grid array module 104 may be soldered to the redistribution pads 98 in the redistribution layer 102 by a plurality of the solder interconnects 96. The imaging module 100 may be used in the imaging sensor array 70, shown in FIG. 5, in place of one or more of the imaging modules 50. With this configuration, an imaging subassembly 106, shown in FIG. 9, may be assembled for individual testing before subsequent attachment to the redistribution layer 102.

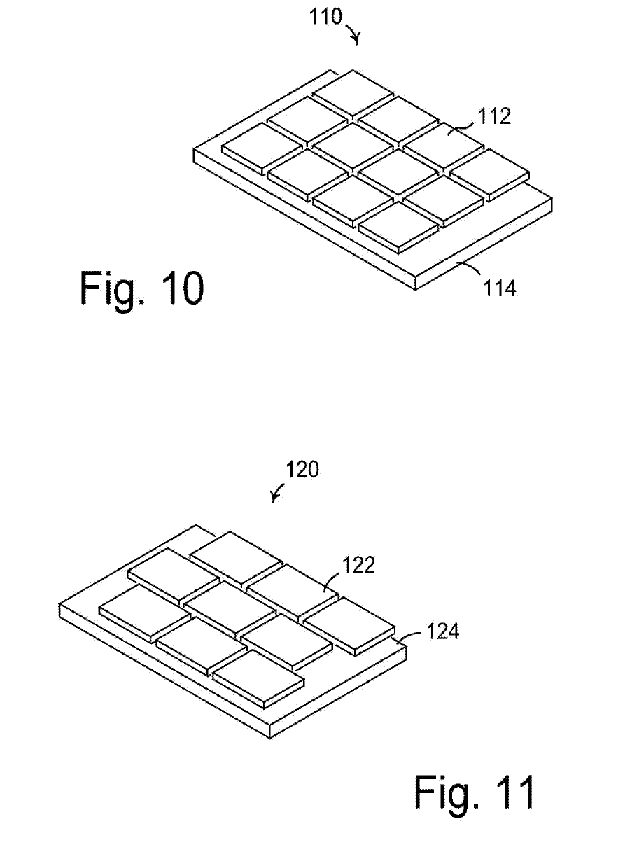

The shapes of the imaging modules 50, 80, 90, and 100 may be selected and specified in accordance with an optimal geometric arrangement used for a particular imaging sensor array 70. FIG. 10, for example, shows an imaging sensor array 110 having a two-dimensional, x-y array of a plurality of generally square imaging modules 112 disposed on a generally planar substrate 114. Note that the outer layer 78 and the thermal plastic conductive adhesive 76 have been omitted for clarity of illustration. Also, spacing between adjacent imaging modules 112 has been exaggerated to more clearly show individual modules. It can be appreciated by one skilled in the art that the imaging modules 112 may be positioned in relatively close proximity to one another to provide an efficient coverage of the surface area available to incoming radiation. This packaging configuration will allow for very close proximity positioning for an array of modules, as a result of the direct conversion crystal having a larger size (i.e., the length and width, or x-y dimensions) than the size of the underlying integrated circuit. This approach can produce a very high-density tileable array of modules in order to maximize the efficiency of the spectral performance of the corresponding image sensor array.

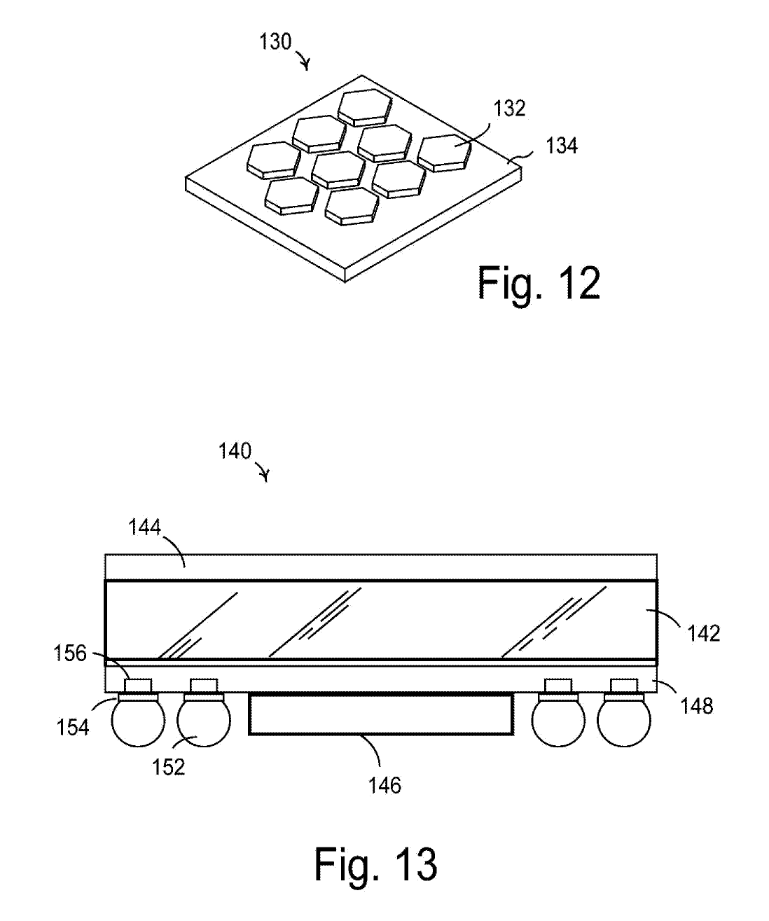

In an alternative exemplary embodiment, shown in FIG. 11, an imaging sensor array 120 may have a “staggered” x-y array of a plurality of generally rectangular imaging modules 122 disposed on a generally planar substrate 124. In yet another alternative embodiment, shown in FIG. 12, an imaging sensor array 130 may comprise a two-dimensional close-packing array of hexagonally shaped imaging modules 132 disposed on a substrate 134. It should be understood that the stack up configurations of the imaging modules 112, 122, and 132 are substantially similar to the stack up of the imaging module 50 shown in the diagrammatical end view of FIG. 4.

An alternative configuration of an imaging module is shown in FIG. 13. Imaging module 140 comprises a direct conversion crystal 142, a cathode layer 144, and an integrated circuit 146 disposed on a redistribution layer 148 in a configuration similar to that of the imaging module 50, as described above. The redistribution layer 148 is configured to adapt the pad array layout (not shown) of the direct conversion crystal 142 to a fan-out of input/output pads forming a perimeter array to accommodate a ball grid assembly (not shown). A plurality of solder balls 152 may be provided at corresponding perimeter pads 156 in the redistribution layer 148 with solder ball pads 154 on the surface of the redistribution layer 148. With this configuration, the solder ball pads 154 can then be used to solder attach the solder balls 152 to the redistribution layer 148, substantially as shown.

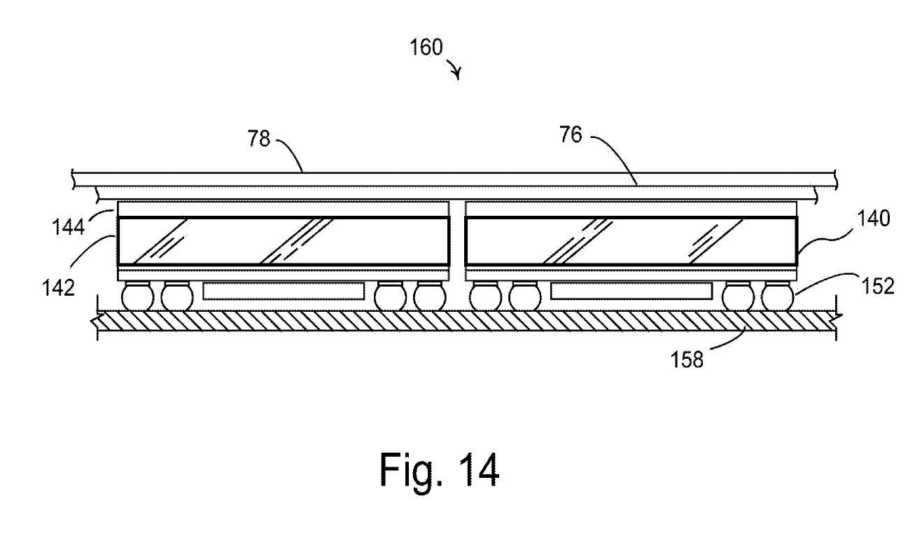

An imaging sensor array 160 may be fabricated with a plurality of the imaging modules 140 electronically connected by any of a plurality of area array ball interconnect configurations, as shown in the diagrammatical side view of FIG. 14. By using conventional second-level soldering technology, for example, the solder balls 152 of the imaging modules 140 can be attached to a support structure 158, such as a carrier fabricated from a material having a low coefficient of thermal expansion. The outer layer 78 may be attached to the cathode layers 144 of the plurality of imaging modules 140 by the thermal plastic conductive adhesive 76, as described above. The flow temperature of the solder alloy forming the solder balls is preferably compatible with the maximum temperature to which the direct conversion crystal 142 can be exposed without damage, for example, a sixty to ninety second solder reflow dwell time, or less, at a maximum temperature of about 160° C.

That is, in an exemplary embodiment, the solder alloy may have an assembly temperature that is less than a maximum temperature to which the direct conversion crystal 142 can be exposed without damage. As known in the relevant art, the maximum exposure temperature for CdZnTe, for example, can be as high as 160° C., if the exposure time is on the order of 90 seconds or less. However, if the maximum exposure temperature is on the order of 80° C., the exposure time can be increased to one or more hours. An exemplary solder alloy suitable for use in the solder balls 152 of the imaging sensor array 160 is a ternary alloy containing tin, bismuth, and lead (Sn—Bi—Pb), which melts at approximately 95° C. Moreover, by using a solder hot air rework tool (not shown), for example, an individual imaging module can be removed and replaced from the imaging sensor array 160, if required.

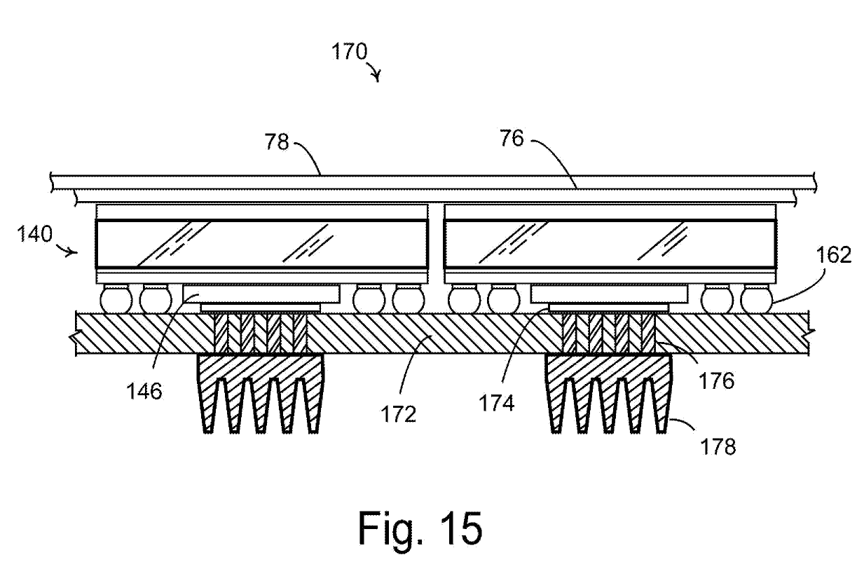

In an alternative exemplary embodiment using solder assembly, an imaging sensor array 170, shown in FIG. 15, comprises a plurality of the imaging modules 140 attached to a support structure 172, such as a carrier, with a plurality of electrically-conductive balls, such as solder balls 162. The support structure 172 may include a plurality of metal-filled through holes, or thermal vias 176, for providing thermal conductive paths to aid in the removal of heat buildup in the imaging sensor array 170. A thermal interface pad 174 may be provided between one or more of the integrated circuits 146 and the support structure 172 proximate the thermal vias 176. One or more heat sinks 178 may be provided on the thermal vias 176, opposite the thermal interface pads 174, for dissipation of thermal energy substantially as shown.

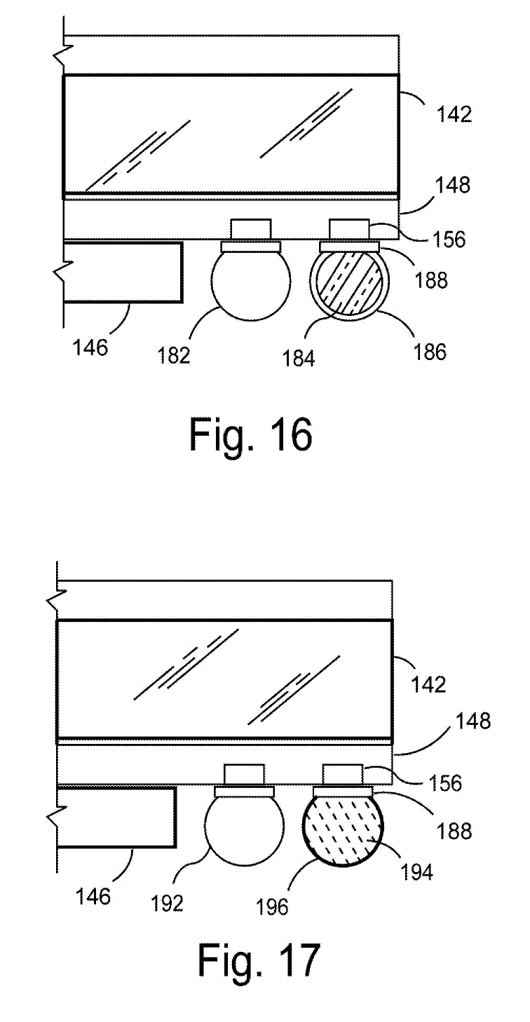

As shown in FIG. 16, one or more of the electrically-conductive balls attached to the redistribution layer 148 may comprise a metal coated resilient ball 182. As shown in cross section, the metal-coated resilient ball 182 may include a spherical interior 184 formed of a resilient material, such as plastic. The metal-coated resilient ball 182 may also have an outer coating 186 of a metal, such as a layer of Ni plating with a surface gold (Au) finish. The metal-coated resilient ball 182 may be commercially available, for example, as one of the conductive fine particle products manufactured by Sekisui Chemical Co., Ltd., Osaka, Japan. With this configuration, a conductive adhesive 188 can be used to attach the metal-coated resilient ball 182 both to the redistribution pad 156 and to the support structure 172 (not shown). Alternatively, as shown in FIG. 17, one or more of the electrically conductive balls attached to the redistribution layer 148 may comprise an Au-coated copper ball 192. As shown in cross section, the Au-coated copper ball 192 may include a spherical copper interior 194 with an outer coating 196 of gold. In this configuration, the conductive adhesive 188 can be used to attach the Au-coated copper ball 192 both to the redistribution pad 156 and to the support structure 172 (not shown).

While the present invention is described with reference to various exemplary embodiments, it will be understood by those skilled in the art that various changes may be made and equivalence may be substituted for elements thereof without departing from the scope of the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. In particular, certain modifications may be made to the teachings of the invention to adapt to a particular situation without departing from the scope thereof. Therefore, it is intended that the invention not be limited to the embodiments disclosed above for carrying out this invention, but that the invention include all embodiments falling within the scope of the intended claims.

What is claimed is:

1. A detector module comprising:
a direct conversion crystal for converting incident photons into electrical signals, said direct conversion crystal having an anode layer deposited on a first surface and a cathode layer deposited on a second surface;
a redistribution layer deposited on said anode layer, said redistribution layer configured to adapt a pad array layout of said direct conversion crystal to a predetermined lead pattern;
an integrated circuit in electrical communication with said direct conversion crystal; and
a plurality of input/output electrical paths connected to said redistribution layer to provide connectivity between said imaging module and another level of interconnect.

2. The detector module of claim 1, wherein said input/output electrical path comprises one of a solder ball, a metal coated resilient ball, and a gold-coated copper ball attached to a redistribution pad in said redistribution layer.

3. The detector module of claim 1, wherein said integrated circuit is attached to said redistribution layer by at least one of a routing substrate, a soldered lead, a flip chip attachment, a metal coated resilient ball, a column grid array module, and a wire bond.

4. The detector module of claim 3, wherein said plurality of input/output electrical paths comprises a flex pigtail attached to one of said redistribution layer and routing substrate.

5. The detector module of claim 1, wherein said direct conversion crystal is larger in size than said integrated circuit.

6. The detector module of claim 1, wherein said direct conversion crystal provides electrical signals in response to incident radiation from an x-ray source.

7. An imaging sensor array comprising:
a support structure;
a plurality of imaging modules attached to said support structure, at least one of said imaging modules including a redistribution layer attached to an anode layer on a direct conversion crystal;
an outer layer overlying and attached to said plurality of imaging modules by a thermal plastic conductive adhesive; and
a plurality of input/output electrical paths connected to said imaging modules to provide connectivity between said imaging sensor array and a second level support structure.

8. The imaging sensor array of claim 7, wherein at least one of said imaging modules comprises an integrated circuit attached to said redistribution layer by at least one of a routing substrate, a soldered lead, a flip chip attachment, a metal coated resilient ball, a column grid array module, and a wire bond.

9. The imaging sensor array of claim 8 wherein at least one of said input/output electrical paths comprises a plurality of area array ball interconnect configurations having an assembly temperature lying substantially within the range of 80° C. to 160° C.

10. The imaging sensor array of claim 9 wherein said plurality of area array ball interconnect configurations comprises a plurality of alloy solder balls attached to said second level support structure by a ternary alloy containing tin, bismuth, and lead.

11. The imaging sensor array of claim 7, further comprising at least one thermal interface pad disposed between one of said imaging modules and said support structure.

12. The imaging sensor array of claim 7, wherein said at least one of said support structure and said second level support structure comprises a material having a low coefficient of thermal expansion.

13. The imaging sensor array of claim 7, wherein at least one of said support structure and said second level support structure comprises a copper rail.

14. The imaging sensor array of claim 7, wherein said support structure comprises at least one conductor pass-thru opening to provide for connectivity between said imaging sensor array and said second level support structure via said input/output electrical paths.

15. The imaging sensor array of claim 7, wherein said support structure comprises at least one thermal via for providing a thermal conductive path to aid in the removal of heat buildup from said imaging sensor array.

16. The imaging sensor array of claim 13, further comprising a heat sink disposed proximate said at least one thermal via.

17. The imaging sensor array of claim 7, wherein a mounting surface of said support structure comprises a substantially planar shape, a substantially convex shape, or a substantially concave shape.

18. A method of fabricating an imaging sensor array, said method comprising the steps of:
providing a plurality of imaging modules, each said imaging module fabricated from a direct conversion crystal having a redistribution layer for attaching a readout integrated circuit to an anode layer on said direct conversion crystal, each said readout integrated circuit being smaller in size than said direct conversion crystal;
attaching said plurality of imaging modules to a support structure in a predetermined pattern; and
providing a plurality of input/output electrical paths between said imaging modules and another level of interconnect.

19. The method of claim 18, wherein said step of attaching comprises the step of soldering said plurality of imaging modules to said support structure using a plurality of conductive balls.

20. The method of claim 18, wherein said step of providing comprises the step of attaching a flex attachment to at least one of said redistribution layers.
